(19) United States
(12) Patent Application Publication
(10) Pub. No.: US 2026/0333625 A1
(43) Pub. Date: Oct. 22, 2026

(54) ROTATING ELECTRONICS TRAY AND LEAK CONTAINMENT SYSTEM

(71) Applicant: AMD Design, LLC, Wilmington, DE (US)

(72) Inventors: Chen AN, Bergenfield, NJ (US); Rukang HUANG, East Williston, NY (US); Mahesh Kumar VARREY, Lincroft, NJ (US)

(73) Assignee: AMD Design, LLC, Wilmington, DE (US)

(21) Appl. No.: 19/184,256

(22) Filed: Apr. 21, 2025

(51) Int. Cl. H05K 7/20; H05K 7/14

(52) U.S. Cl. CPC H05K 7/20272; H05K 7/1487; H05K 7/20763

(57) ABSTRACT

A method and system to contain liquid coolant leaks in a rack that includes an electronics tray having a plurality of electronics components mounted on a mounting board, the electronics tray including a liquid coolant system having a liquid coolant for cooling the electronics components, wherein the electronics tray is moveable, preferably rotatable, between an operational position where the mounting board is located above the electronics components and a servicing position where the mounting board is located below the electronics components. In the operational position the electronics tray is configured so that any leaks of the liquid coolant from the liquid coolant system flow away from the mounting board by the influence of gravity. The system and method further including positioning a leak container below the electronics tray for collecting any liquid coolant in response to a leak of the liquid coolant.

### FIELD

This disclosure is directed to leak containment of, and access to, a liquid coolant system and associated mounting board within a server.

### BACKGROUND

A plurality of electronic components (e.g., hard drives, integrated circuits, networking equipment, graphics processing units (GPUs), central processing units (CPUs), etc.) are often assembled on printed circuit boards, also referred to as mounting boards. The printed circuit boards are then assembled on electronics trays which are inserted, installed, and connected together in server racks. The electronics trays can be mounted in drawers, which can be pulled out and/or removed from the servers and/or electronic racks for servicing.

Many times, at least one of the electronic components is liquid cooled. That is, the electronic component is cooled using a cold plate with liquid coolant flowing therethrough. Containing leaks from such cooling systems (e.g., the cold plate, connectors, hoses, etc.) is important to mitigate risk associated with the leaks (e.g., shorting of components). As the mounting boards are often mounted right-side up (e.g., the cooling systems are on top of the electronic components which are on top of the mounting boards), the leaks often hit the boards and travel across the boards to a leak container mounted below the boards. Accordingly, there is a high risk that components of the board (or other components of a server) can be damaged by the leaking liquid coolant.

### SUMMARY

A rotating electronics tray and leak containment system is disclosed. In one or more embodiments, the electronics tray is configured to be mounted in an electronics drawer, a server, and/or a rack so that electronics components and a liquid coolant system (e.g., one or more cold plates, one or more manifolds, quick disconnect couplers, and/or supply and return hoses) that are attached to the electronics tray are, when the electronics tray is in an operational position, disposed below the electronics tray and/or at least one mounting board on which the electronics components and the liquid coolant system is mounted. In other words, in the operational position, the mounting board and liquid coolant system are upside down. In this way, any liquid coolant that leaks from the liquid coolant system can drip away from the electronic components and/or the mounting board and into a leak container positioned underneath the liquid coolant system. To provide better serviceability, the electronics tray (and, thus, the mounting board) can be rotated to a service position where the electronics components are facing up (e.g., right-side up). That is, the electronics tray can be rotated such that the mounting board is located below the electronics components and the liquid coolant system.

A system is also described herein. The system includes the electronics tray above and a drip containment tray. The electronics tray may be rotatably attached to the drip containment tray or to an intermediate component (e.g., a drip containment frame, a server slide, a server housing, etc.)

A server is also described herein. The server includes the system above attached to a server chassis and at least one mounting board with a liquid coolant system attached thereto attached to the electronics tray.

A method of operating a rotating electronics tray and leak containment system is also disclosed. The method includes receiving a system with an electronics tray in a service position where the electronics tray is not above a leak container of the system. The method also includes attaching at least one mounting board with a liquid coolant system to the electronics tray while the electronics tray is in a service position. The method further includes rotating the electronics tray to an operational position where the electronic tray and, thus, the mounting board and liquid coolant system, are above the leak container. In this way leaks from the liquid coolant system will flow directly into the leak container via gravity.

The foregoing summary is illustrative only and is not intended to be in any way limiting. In addition to the illustrative aspects, implementations, and features described above, further aspects, implementations, and features will become apparent by reference to the drawings and the following detailed description. In the drawings, like reference numbers indicate identical or functionally similar elements.

### BRIEF DESCRIPTION OF THE DRAWINGS

FIG. 1 illustrates a perspective view of an example rack containing a plurality of servers.

FIG. 2 illustrates a perspective view of a schematic diagram of an example server having an electronics drawer having an electronics tray where the electronics drawer and electronics tray is mounted within the server and/or rack in an operational mode where the electronics tray and electronics components are operational according to an embodiment of the disclosure.

FIG. 3 illustrates a perspective view of the example server with the electronics drawer and electronics tray of FIG. 2 being prepared for servicing according to an embodiment of the disclosure.

FIG. 4 illustrates a perspective view of the example server with the electronics drawer and electronics tray of FIG. 2 being further prepared for servicing according to an embodiment of the disclosure.

FIG. 5 illustrates a perspective view of an example server that includes an electronics tray where the server and electronics tray are positioned in an operational mode where the electronics tray is in an operational position according to another embodiment of the disclosure.

FIG. 6 illustrates a perspective view of the example server and electronics tray of FIG. 5 being prepared for servicing where access is gained to the electronics tray according to an embodiment of the disclosure.

FIG. 7 illustrates a perspective view of the example server and electronics tray of FIG. 5 being prepared for servicing where the electronics tray is slide out of the server according to an embodiment of the disclosure.

FIG. 8 illustrates a perspective view of the example server and electronics tray of FIG. 5 being prepared for servicing where the electronics tray has been rotated to a servicing position according to an embodiment of the disclosure.

### DETAILED DESCRIPTION

### Overview

Racks containing electronic components, such as, server racks, computing racks, networking racks, etc., generally contain multiple servers. The servers usually contain electronics trays, which in example configurations are arranged in the servers and/or electronics drawers and are capable of being slide out of the rack and/or server. The racks are often liquid cooled and generally the servers, the electronics drawers, and/or the electronics trays have a liquid cooling system that contains a liquid coolant and in one or more embodiments usually has one or more cold plates, a liquid coolant conduit system, quick disconnect couplers, and supply and return liquid coolant hoses. For liquid cooled components in a rack, including liquid cooled electronics trays, drawers, and/or servers, collecting, capturing, and/or containing liquid coolant that leaks from the liquid coolant system and disposing of the leaked liquid coolant often leads to service difficulties, especially at the individual chip level.

It would be advantageous to have a system, mechanism, product, and/or technique in racks, electronics drawers, and/or electronics trays where leaks of the liquid coolant system are easier to contain and will result in less damage to the components in the rack and further advantageous if such system, mechanism, and/or technique facilitates easy servicing and/or easier disposition of the liquid coolant that leaks from the liquid coolant system.

Described herein is a system, mechanism, product, and/or method for collecting, capturing, and/or containing liquid coolant that leaks from a liquid coolant system in an electronics tray, servers, and/or a rack that results in less damage to the electronics components in the electronic racks, including less damage to the electronics components associated with and/or mounted to electronics trays, in the event of a liquid coolant leak. Also described is a system, mechanism, product, and/or method to facilitate easier disposition of liquid coolant that does leak from a liquid coolant system in a rack and/or electronics tray. Further disclosed is a system, mechanism, product, and/or method that facilitates liquid coolant leak collection and/or containment and that also provides easy servicing, by for example, reorienting the electronics tray.

In one or more arrangements, the system, mechanism, product and/or technique to collect, capture and/or contain liquid coolant leaks in a rack includes an electronics tray having a plurality of electronics components mounted on a mounting board wherein the electronics tray includes a liquid coolant system having a liquid coolant for cooling the electronics components mounted on the mounting board. The electronics tray with the liquid coolant system is configured to be positioned in an operation mode in the rack in an upside-down position so that the mounting board is located above the electronics components mounted to the mounting board so that any leak of the liquid coolant from the liquid coolant system flows away from the mounting board via gravity. The system to collect, capture and/or contain the liquid coolant in response to a liquid coolant system leak includes, in one or more embodiments, a leak container positioned below the electronics tray for collecting any liquid coolant in response to a leak of liquid coolant from the liquid coolant system contained on and/or associated with the electronics tray.

In one or more configurations, the system, mechanism, product, and/or technique permits and/or facilitates reorientation of the electronics tray and/or mounting board for servicing the electronics components on the electronics tray, and in an embodiment so service can occur at individual chips and heatsinks. In one or more embodiments the electronics tray and/or mounting board are reoriented by rotating the electronics tray and/or mounting board from its upside-down position (e.g., an operational position) to a servicing position, by in one or more configurations rotating the electronics tray, preferably anywhere between approximately 165 degrees to approximately 195 degrees, more preferably about 180 degrees. In one or more arrangements, a single leak container can serve more than one heatsink, and preferably the leak container does not need to be sealed against the mounting board and/or the heatsinks. In one or more embodiments, the drain path of the liquid coolant is below the mounting board and can potentially save the mounting board during liquid coolant leaks that would otherwise ruin the mounting board and/or the electronics components mounted on the mounting board.

Further described is one or more example methods of building racks with a plurality of electronics trays that include a technique for capturing and/or containing liquid coolant that leaks from a liquid coolant system incorporated into an electronics tray and/or rack that includes positioning the electronics tray containing a plurality of electronics components mounted on a mounting board so that the electronic components are positioned and/or located below the mounting board so that in response to liquid coolant leaking from the liquid coolant system the liquid coolant flows via gravity away from the mounting board. That is, the electronics tray is mounted in the rack and/or electronics drawers in an upside-down orientation. In an approach, the method further includes positioning a leak container underneath the electronics tray so that in response to liquid coolant leaking from the liquid coolant system the liquid coolant is collected, contained, and/or captured in the leak container.

A method of servicing an upside-down electronics tray is also disclosed that includes in one or more embodiments, reorienting, preferably rotating, the electronics tray for servicing of the electronics tray, where in one or more approaches the electronics tray is rotated anywhere between 165 to 195 degrees, more preferably about 180 degrees.

In the following description, numerous specific details are set forth, such as particular structures, components, materials, dimensions, processing steps and techniques, in order to provide an understanding of the various implementations of the present application. However, it will be appreciated by one of ordinary skill in the art that the various implementations of the present application may be practiced without these specific details. In other instances, well-known structures or processing steps have not been described or illustrated in detail in order to avoid obscuring the present application.

### Example Environment

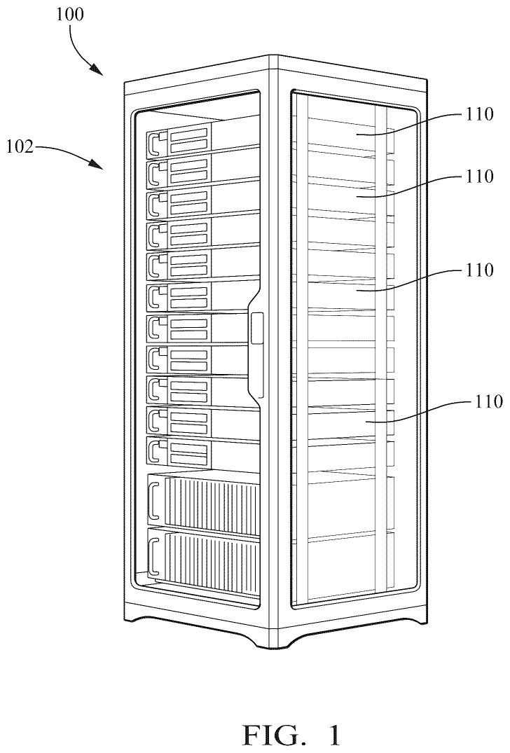

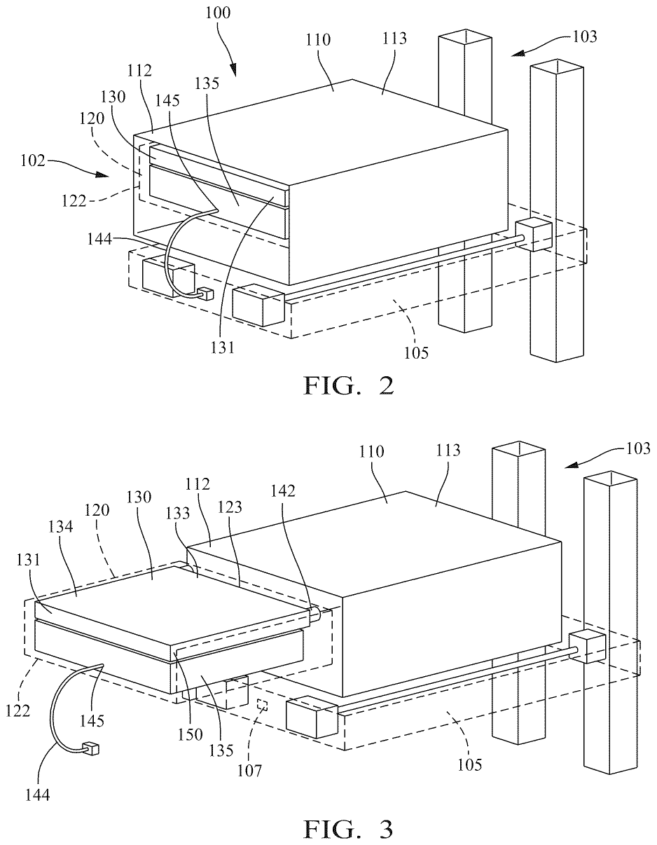

FIGS. 1-2 illustrate an example environment for containing liquid coolant leaks from an electronics tray in a rack. FIG. 1 illustrates a perspective view of a rack 100 (e.g., a server rack, electronics rack, computer rack, and/or networking rack) that has a plurality of servers 110 (e.g. electronics servers, computing servers, network servers, graphics (GPU) servers, and/or artificial intelligence (AI) servers). The servers 110, as illustrated in FIG. 2, include one or more electronics drawers 120 that contain one or more electronics trays 130 where the one or more electronics trays 130 include electronics components 132, e.g., GPUs and/or CPUs, positioned, arranged on, and/or mounted to at least one mounting board 134, e.g., printed circuit board. In one or more arrangements, the electronic drawers 120 further include at least one leak container 135 (e.g., drip tray) for each electronic tray 130. The at least one leak container 135 in one or more arrangements are located below and/or underneath the electronics tray 130. A single container may simplify assembly and maintenance and reduce cost, although multiple containers may be disposed without departing from the scope of this disclosure.

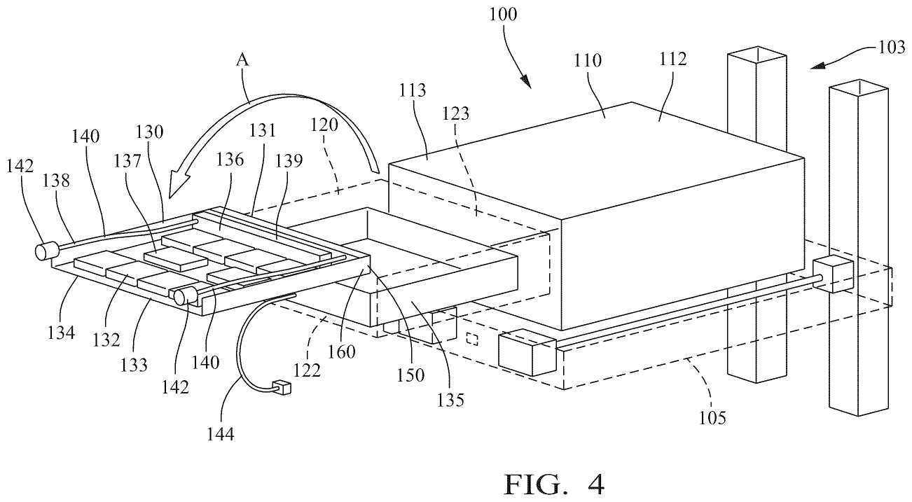

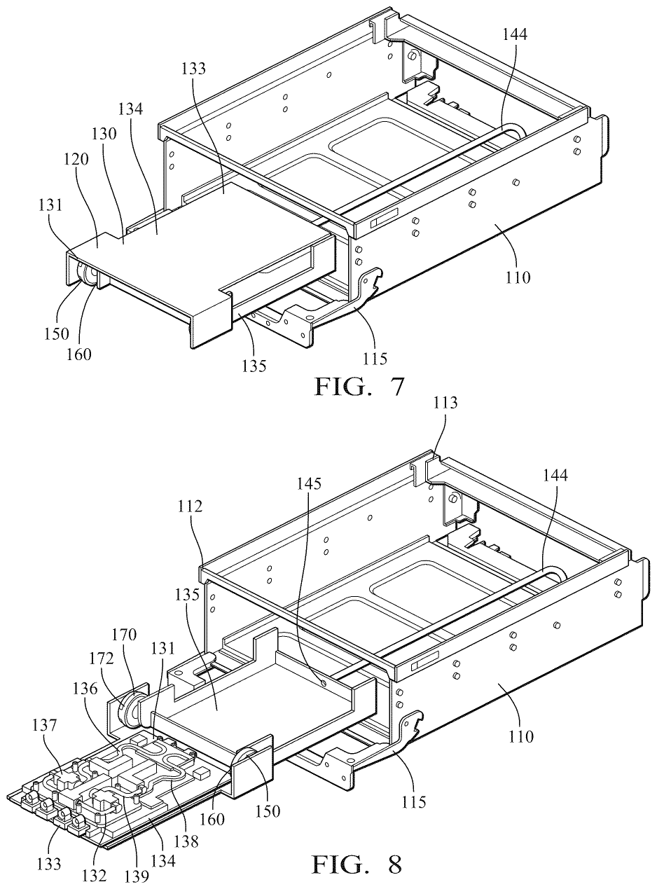

The electronics tray 130 in one or more embodiments includes a liquid coolant system 136, which can optionally include one or more cold plates 137 and/or a liquid coolant conduit system 138 for transporting a liquid coolant 139 (See FIGS. 4 and 8). The electronics tray 130, electronics drawer 120, the server 110, and/or rack 100 in one or more embodiments includes coolant hoses 140 (one or more supply and return hoses) and/or one or more quick disconnect couplers 142. In an embodiment, the rack 100 further includes a main leak pan 105 into which liquid coolant 139 can drain from leak container 135. In an embodiment, a drain hose 144 can connect a drain 145 in leak container 135 to main leak pan 105 to carry any liquid coolant 139 collected and/or captured in leak container 135 to main leak pan 105.

### Example Implementation

FIGS. 2-4 illustrate an example implementation of a mechanism 150 and/or method of containing liquid coolant 139 that leaks from liquid coolant system 136 in a rack 100, and more specifically capturing, collecting, and/or containing liquid coolant 139 that leaks from an electronics tray 130 that contains a liquid coolant system 136 (see FIGS. 4 and 8). For example, an electronics tray 130 includes a mounting board 134 for mounting a plurality of electronics components 132 where the electronics tray 130 includes a liquid coolant system 136 containing liquid coolant 139. The liquid coolant system 136 can take on many forms and can include one or more cold plates 137, one or more heat sinks, a liquid coolant conduit system 138 for transporting the liquid coolant between electronics components 132, cold plates, 137, and/or heat sinks associated with the electronics tray 130. The electronics tray 130 can in one or more arrangements include one or more quick disconnect couplers 142, which in an embodiment connect to one or more coolant hoses 140 to transport liquid coolant 139 between servers 110, electronic drawers 120, and/or electronic trays 130.

The electronics tray 130 in one or more embodiments is configured, positioned, and/or mounted in and secured to the rack 100 in an upside-down position where the electronics components 132 are located and/or positioned underneath the mounting board 134 to which the electronics components 132 are mounted and/or attached. In this manner, if liquid coolant 139 should leak from the liquid coolant system 136, the liquid coolant 139 will not flow toward and/or collect on the mounting board 134 and should not damage the electronics tray 130, the electronics components 132, e.g., the GPUs and/or CPUs, and/or mounting board 134. In one or more embodiments, at least one leak container 135 is located and/or positioned beneath and/or underneath the electronics tray 130, e.g., beneath and/or underneath the electronics components 132 and/or mounting board 134, to capture, collect, and/or contain any liquid coolant 139 in response to any leak of liquid coolant 139 from the liquid coolant system 136. A single container may simplify assembly and maintenance and reduce cost, although multiple containers may be disposed without departing from the scope of this disclosure. With the electronics tray 130 in an upside-down position as shown in FIG. 2, the rack 100 is in an operational mode where the electronics tray 130, including the electronic components 132 mounted on the mounting board 134, are operational and in an operational position.

To service the electronics tray 130, e.g., the GPU board, the electronics drawer 120 containing the electronics tray 130 and/or the leak container 135 are pulled out of the server 110 and/or rack 100 as shown in FIG. 3. The electronics drawer 120 is pulled out of the server 110 so that at least a portion and preferably a substantial portion of the electronics tray 130 is located outside the server 110. For example, in an embodiment, if the electronics drawer 120 is pulled out of the front end 102 of the rack 100 and/or the front end 112 of the server 110, the rear end 133 of the electronics tray 130 clears the rack 100 and/or other servers 110; and in another configuration, if the electronics drawer 120 is pulled out of the rear end 103 of the rack 100 and/or the rear end 113 of the server 110, the front end 131 of the electronics tray 130 clears the rack 100 and/or the other servers 110 so that the electronics tray 130 can be reoriented, preferably flipped over, for servicing as shown in FIG. 4.

That is, in an embodiment, the electronics drawer 120 containing the electronics tray 130 and preferably the leak container 135 are both pulled out of the server 110 and/or rack 100 as shown in FIG. 3 and then the electronics tray 130 is rotated as shown in FIG. 4 by arrow A to make service on the electronics tray 130, e.g., on the GPU, easier. That is, in one or more arrangements the electronics tray 130 is rotated to the servicing position where the electronics components 132 are facing up and are located above the mounting board 134 to facilitate access, for example, to the electronics components 132.

It can be appreciated that in a configuration, during or before the process of moving the electronics drawer 120 from the server 110 and/or rack 100, the quick disconnect couplers 142 are disconnected from the coolant hoses 140. It can be appreciated that in another arrangement, during or before the process of moving the electronics drawer 120 from the server 110 and/or rack 100, the quick disconnect couplers 142 remain connected to the coolant hoses 140 and enough slack is provided in the coolant hoses 140 to permit movement of the electronics drawer 120 and/or electronics tray.

It can be appreciated, that the leak container 135 can be moved and/or slide out of the server 110 and/or rack 100 with the electronics tray 130 as shown in FIGS. 3-4, or in an optional embodiment the leak container 135 can remain stationary and/or not move or slide out of the server 110 and/or rack 100 to the same extent as the electronics tray 130. The leak container 135 in one or more embodiments can be independently moveable in the rack 100, the server 110, and/or the electronics drawer 120. In an arrangement, during or before the operation of moving the electronics drawer 120 from the server 110 and/or rack 100, including moving the leak container 135 from the server 110, the electronics drawer 120, and/or rack 100, the drain hose 144 can be disconnected from the drain 145 of the leak container and/or from the drain 107 of main leak pan 105.

In a further arrangement, during or before the operation of moving the electronics drawer 120 from the server 110 and/or rack 100, including moving the leak container 135 from the electronics drawer 120, the server 110, and/or the rack 100, the drain hose 144 can remain connected to the drain 145 of the leak container 135 and remain connected to the drain 107 of main leak pan 105 and enough slack in the drain hose 144 is provided to permit movement of the leak container 135. In an arrangement where the leak container 135 remains stationary and is not pulled out of the electronics drawer 120, server 110, and/or the rack 100 with and/or after the electronics tray 130, the drain hose 144 can remain connected to the drain 145 of the leak container 135 and remain connected to the drain 107 of main leak pan 105, and the drain hose 144 can be configured to have no slack or can be configured to have slack to permit movement of the leak container 135 and/or the main leak pan 105.

As shown in FIG. 4, to facilitate easier service of the electronics tray 130, e.g., the electronic components 132, the electronics tray 130 is reoriented, preferably flipped over so that the electronics components 132 are located above the mounting board 134 and are facing up. In one or more arrangements the electronics tray 130 is rotated from its operational position to a servicing position where the servicing position is up to 270 degrees rotated from the operational position. In one or more configurations, the electronics tray is rotated between about 165 degrees and 195 degrees from the operational position to the servicing position, and in an approach is rotated 180 degrees from the operational position to the servicing position. It can be appreciated, that the electronics tray 130 can be rotated more or less than shown in FIGS. 3-4 and described above, which will in part depend upon the operational position and the servicing position and the configuration of the servers 110 and/or rack 100.

In one or more configurations, the electronics tray 130 is rotated by a force being applied, for example by a user, to the rear end 133 of the electronics tray 130 to rotate the electronics tray 130 to the servicing position. To facilitate rotating of the electronics tray 130, a rotating mechanism 150 is provided preferably at one end, for example the front end 131 of the electronics tray 130. The rotating mechanism 150 in an example configuration includes one or more hinges 152. The rotating mechanism 150 can for example include one or more axles and/or pins about which the electronics tray 130 can rotate and/or pivot. The rotating mechanism 150, the electronics tray 130, and/or the electronics drawer 120 can further include a holding mechanism 160 to hold the electronics tray 130 in the servicing position. That is, holding mechanism 160 can include stops, e.g., structure, that inhibit, impede, and/or prevent further rotation of the electronics tray 130 beyond the servicing position. For example, the rotating mechanism 150 can be one or more hinges that have a stop (e.g., one or more tabs) forming the holding mechanism 160.

In some implementations, leak container 135 and/or electronics tray 130 may be mounted to an intermediate structure. For example, leak container 135 and/or electronics tray 130 may be mounted to a frame that includes hinges 152. The intermediate structure may contain one of leak container 135 or electronics tray 130. Regardless of how they are coupled (e.g., via intermediate structures, hinges, etc.), electronics tray 130 is configured to rotate relative to leak container 135.

A damping mechanism 170 can be added to the electronics tray 130 and/or the rotating mechanism 150 to dampen the rotational movement of the electronics tray 130. In one or more approaches, hydraulic and/or pneumatic damping can form the damping mechanism 170 and can be added to the rotating mechanism 150 to limit (e.g., slow) the rotational speed of the electronics tray 130 and avoid harsh impacts or jarring movements of the electronics tray 130. In one or more arrangements, a torsional speed limiter 172 and/or biasing member 174 can be used to assist with rotating the electronics tray 130, and can further be configured to lessen, inhibit, and/or prevent damaging the electronics tray 130 in case of user error in rotating the electronics tray 130. For example, the biasing member 174 can be configured to apply a force to assist with rotating the electronics tray 130 to the servicing position and/or to apply a force to limit the rotational speed of the electronics tray 130. Additionally, and/or alternatively, a torsional speed limiter 172 can be included to assist with (e.g., facilitate) and/or limit (e.g., impede) rotation of the electronics tray 130.

In a further embodiment, an actuator and/or electric motor can be used to rotate the electronics tray 130 and/or slide out the electronics tray 130, the leak container 135, and/or electronics drawer 120 from the server 110 and/or the rack 100. For example, an actuator and/or electric motor can apply a torque to the rotating mechanism 150, e.g., one side of a hinge, one or more axles and/or pins on which the electronics tray is mounted and about which the electronics tray 130 rotates.

### Further Implementations

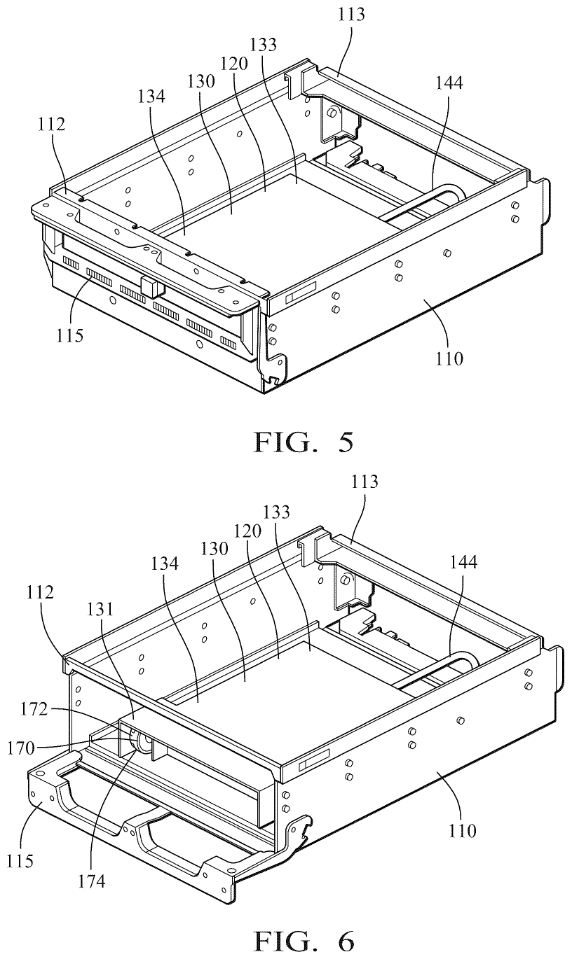

FIGS. 5-8 illustrates an exemplary embodiment of capturing, collecting, and/or containing liquid coolant 139 that leaks from a liquid coolant system 136 of an electronics tray 130. FIG. 5 illustrates an server 110 that is capable of being moved, e.g., slid, out of a rack 100 where the server 110 includes an electronics drawer 120 that is capable of being moved, e.g., slide, out of an server 110. The server 110 as shown in FIG. 5, located in the rack 100, is in an operational mode in an operational position where the electronics tray is positioned upside-down in the rack 100 and/or server 110 such that the electronic components 132 are located below the mounting board 134. In this manner, any leaks of liquid coolant 139 from the liquid coolant system 136 on the electronics tray 130 flows away from the mounting board 134 via gravity (e.g., under the influence of gravity). Preferably, in an embodiment, any liquid coolant 139 that does leak from the liquid coolant system 136 is collected in leak container 135.

To facilitate servicing the electronics tray 130, e.g., the electronic components 132, e.g., the GPU, the server 110, e.g., the GPU server, is moved, e.g., slid, out of the rack 100 and access is gained to the electronics tray 130 as shown in FIG. 6 by for example, moving a front door 115. As shown in FIG. 6, front door 115 is rotated and/or pivoted to permit and/or facilitate movement of electronics tray 130. While the front door is illustrated as being rotated out of the way to obtain access to the server 110, the electronics drawer 120, and/or the electronics tray 130, it can be appreciated that other doors, mechanisms to move the front door 115 can be provided, and in other examples no front door 115 may be provided.

As shown in FIG. 7, the electronics tray 130 and/or the electronics drawer 120 is slid out of the server 110. In an embodiment both the electronics tray 130 and the leak container 135 are both slid out of the server 110, although it can be appreciated that in an arrangement only the electronics tray 130 is slid out of the server 110 and the leak container 135 remains located within the server 110. In an embodiment where the leak container 135 is slid out of the server 110, the drain hose 144 remains connected to the drain 145 in the leak container 135 and in a configuration slack is provided in drain hose 144 to permit and/or facilitate movement of leak container 135.

With the electronics tray 130 moved out of the server 110, the electronics tray 130 is flipped over, e.g. reoriented and/or rotated, to a servicing position as shown in FIG. 8 so that the electronics components 132 are facing up and are located above the mounting board 134 to facilitate servicing. That is the electronics tray is flipped over, e.g., rotated between approximately 165 and 195 degrees, more preferably about 180 degrees, so that access to the electronic components 132, e.g., the GPUs, is increased to permit and/or facilitate servicing of the electronics tray 130. The electronics tray 130 and/or server 110 (and/or the electronics drawer 120 if present) is provided with a rotating mechanism 150 to facilitate and permit rotating of the electronics tray as shown in FIG. 8. To facilitate rotating of the electronics tray 130, a rotating mechanism 150 is provided preferably at one end, for example the front end 131 of the electronics tray 130. The rotating mechanism 150 in an example configuration includes one or more hinges 152. The rotating mechanism 150 can for example include one or more axles and/or pins about which the electronics tray 130 can rotate and/or pivot.

The electronics tray 130, the rotating mechanism 150, and/or server 110 (and/or the electronics drawer 120 if present) in one or more arrangements includes a damping mechanism 170 that may take the form of a hydraulic and/or pneumatic damping device, and/or a torsional speed limiter 172, including optionally a biasing member 174. The damping mechanism 170 in a configuration limits the speed at which the electronics tray rotates to lessen and/or avoid damage to the electronics tray 130. In one or more arrangements a spring or other biasing member can be applied to the rotating mechanism 150 to assist with and/or facilitate rotating the electronics tray 130. In one or more arrangements a spring or other biasing member (for example, biasing mechanism) can be applied to impede rotational movement of the electronics tray 130.

The electronics tray 130, rotating mechanism 150, the rack 100, the server 110, and/or the electronics drawer 120 if present, can include a holding mechanism 160 to hold the electronics tray in the servicing position and in an embodiment the holding mechanism 160 can further limit the amount of rotation that the electronics tray 130 can undergo. The holding mechanism 160 can include structure, e.g., a tab, that interferes with, contacts, and/or is blocked from further rotational movement by structure, e.g., a tab, on leak container 135. For example, rotating mechanism 150 can be one or more hinges that have a stop (e.g., one or more tabs) forming the holding mechanism 160. Other mechanism to hold, inhibit, impede, and/or prevent further rotation of the electronics tray 130 beyond the servicing position are contemplated.

In a further embodiment, an actuator and/or electric motor can be used to rotate the electronics tray 130 and/or slide out the electronics tray 130, the leak container 135, and/or electronics drawer 120 from the server 110 and/or the rack 100. For example, an actuator and/or electric motor can apply a torque to the rotating mechanism 150, e.g., one side of a hinge, one or more axles and/or pins on which the electronics tray is mounted and about which the electronics tray 130 rotates.

### Examples

Example 1: A system to contain liquid coolant leaks in a rack that includes an electronics tray having a plurality of electronics components mounted on a mounting board, the electronics tray having a liquid coolant system having a liquid coolant for cooling the electronics components mounted on the mounting board, wherein the electronics tray is moveable between an operational position where the mounting board is located above the electronics components mounted on the mounting board and a servicing position where the mounting board is located below the electronics components mounted to the mounting board.
Example 2: The system according to example 1, wherein in the operational position the electronics tray is configured so that any leaks of the liquid coolant from the liquid coolant system flow away from the mounting board by the influence of gravity.
Example 3: The system according to any one of examples 1 or 2, further including a leak container positioned below the electronics tray for collecting any liquid coolant in response to a leak of the liquid coolant from the liquid coolant system.
Example 4: The system according to example 1, wherein the electronics tray is configured to be repositioned to a different orientation in response to moving from the operational position to the servicing position.
Example 5: The system according to example 4, wherein the electronics tray is rotatable from the operational position to the servicing position.
Example 6: The system according to example 5, wherein the electronics tray is rotatable up to about 270 degrees.
Example 7: The system according to example 6, wherein the electronics tray is rotatable approximately 180 degrees from the operational position to the servicing position.
Example 8: The system according to example 1, further including a rotation mechanism to facilitate rotation of the electronics tray.
Example 9: The system according to example 8, wherein the rotation mechanism includes a hinge to permit rotation of the electronics tray.
Example 10: The system according to any one of examples 1-9, further including a damping mechanism to the slow the rotational speed of the electronics tray as it moves between the operational position and the servicing position.
Example 11: The system according to example 10, wherein the damping mechanism comprises at least one of a damping group consisting of: a torsional speed limiter, a biasing member, a hydraulic damping mechanism, a pneumatic damping mechanism, and combinations thereof.
Example 12: The system according to any one of examples 10-11, wherein the damping mechanism further limits the amount of rotation of the electronics tray.
Example 13: The system according to any one of examples 1-12, further including a holding mechanism to hold the electronics tray in the servicing position.
Example 14: The system according to example 13, wherein the holding mechanism includes structure on the electronics tray that interferes with additional structure to block further movement of the electronics tray.
Example 15: A method of containing a leak of liquid coolant in a liquid coolant system of an electronics tray used in a rack, the method including positioning in an operational position an electronics tray comprising a plurality of electronics components mounted to a mounting board, wherein the electronics tray further comprises a liquid coolant system containing a liquid coolant, so that the electronics components are located below the mounting board and so that in response to a leak of the liquid coolant in the liquid coolant system, the liquid coolant flows under the influence of gravity away from the mounting board.
Example 16; The method according to example 15, further including positioning a leak container underneath the electronics tray so that in response to the leak of the liquid coolant in the liquid coolant system, the liquid coolant is contained in the leak container.
Example 17: The method according to examples 15 or 16, further including rotating the electronics tray to a different position to service the electronics tray.
Example 18: The method according to example 17, further including rotating the electronics tray between 165 degrees and 195 degrees to service the electronic tray wherein the mounting board is located below the electronics components mounted on the mounting board.
Example 19: The method according to any one of examples 15-18, further comprising limiting the speed of rotation of the electronics tray
Example 20: The method according to any one of examples 15-19, further comprising limiting the amount of rotation of the electronics tray.
Example 21: The method according to any one of examples 15-20, further including moving the electronics tray horizontally so that at least a substantial portion of the electronics tray is removed from the rack.
Example 22: The method according to any one of examples 15-21, further including moving the leak container horizontally so that at least a substantial portion of the leak container is removed from the rack.
Example 23: The method according to example 22, further comprising moving the leak container horizontally independently from horizontally moving the electronics tray.
Example 24: The method according to any one of examples 15-23, wherein coolant supply hoses and coolant return hoses are disconnected prior to rotating the electronics tray.
Example 25: A system configured to contain liquid coolant leaks from a liquid coolant system mounted to a mounting board, the system comprising: a leak container; and an electronics tray: including a portion configured to accept the mounting board; and rotatable between an operational position where the portion is located above the leak container and a servicing position where the portion is not located above the leak container.
Example 26: The system according to example 25, wherein the electronics tray is configured to rotate around an axis proximate an end of the electronics tray.
Example 27: The system according to example 25 or 26, wherein the electronics tray is configured to rotate around an axis perpendicular to a direction of gravity.
Example 28: The system according to any of examples 25-27, wherein the electronics tray is configured to rotate approximately 180 degrees between the operational position and the servicing position.
Example 29: The system according to any of examples 25-28, wherein the system includes a damping mechanism configured to slow a rotational speed of the electronics tray as it rotates between the operational position and the servicing position.
Example 30: The system according to example 29, wherein the damping mechanism comprises: a torsional speed limiter, a biasing member, a hydraulic damping mechanism, or a pneumatic damping mechanism.
Example 31: The system according to any of examples 25-30, wherein the system includes a holding mechanism configured to hold the electronics tray in the servicing position.
Example 32: The system according to any of examples 25-31, wherein the system is configured to be mounted to an electronics drawer.
Example 33: The system according to example 32, wherein the electronics tray is configured to rotate around an axis perpendicular to a moving axis of the electronics drawer.
Example 34: The system according to any of examples 25-33, wherein the electronics tray is rotatably mounted to the leak container via one or more hinges.
Example 35: The system according to example 34, wherein the hinges are between the leak container and the electronics tray.
Example 36: The system according to any of examples 25-35, wherein the electronics tray and the leak container are mounted to an intermediate structure that includes one or more hinges.
Example 37: The system according to any of examples 25-36, wherein the system is configured such that, when the mounting board is attached to the electronics tray, the liquid coolant system is: below the mounting board in the operational position; and above the mounting board in the servicing position.
Example 38: A server comprising: a chassis; an electronics drawer configured to extend and retract relative to the chassis; a leak container disposed within or attached to the electronics drawer; and an electronics tray: disposed within or attached to the electronics drawer; including a mounting board with a liquid coolant system attached thereto; and configured to rotate relative to the leak container between: an operational position where the liquid coolant system is above the leak container; and a service position where the liquid coolant system is not above the leak container.
Example 39: The server according to example 38, wherein the electronics tray is configured to rotate around an axis perpendicular to a moving axis of the electronics drawer.
Example 40: The server according to example 38 or 39, wherein the electronics tray is configured to rotate approximately 180 degrees between the operational position and the servicing position.
Example 41: The server according to any of examples 38-40, wherein the electronics tray is configured to, when the electronics drawer is extended, rotate away from the chassis between the operational position and the servicing position and toward the chassis between the servicing position and the operational position.
Example 42: A method of servicing a mounting board within a server, the mounting board comprising a liquid coolant system, the method comprising: extending an electronics drawer of the server, the electronics drawer including a system with an electronics tray having the mounting board attached thereto; and rotating the electronics tray relative to a leak container of the system from an operational position where the liquid coolant system is above the leak container to a servicing position where the liquid coolant system is not above the leak container.
Example 43: The method according to example 42, wherein rotating the electronics tray relative to the leak container is facilitated via one or more hinges between the electronics tray and the leak container.
Example 44: The method according to example 42 or 43, wherein the method includes, after servicing the mounting board: rotating the electronics tray relative to the leak container from the servicing position to the operational position; and retracting the electronics drawer.

### Conclusion

The terminology used herein is for the purpose of describing particular implementations only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, components, subsystems and/or groups but do not preclude the presence or addition of one or more other features, integers, steps, operations, elements, components, subsystems, and/or groups thereof. Further, the terms up, upper, down, lower, above, below, left, right, forward, rearward, first, second, third, and the like are intended to be understood in the context of the representations described and illustrated above so that a system, device, product, subsystem, and/or component may have such an orientation in reference to the frame or to various elements as supported by the frame or as illustrated in the drawing or figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various implementations were chosen and described in order to explain the principles of this disclosure and the practical application, and to enable others of ordinary skill in the art to understand this disclosure for various implementations with various modifications as are suited to the particular use contemplated.

What is claimed is:

1. A system for containing liquid coolant leaks from a liquid coolant system mounted to a mounting board, the system comprising:
a leak container; and
an electronics tray including a portion configured to accept the mounting board,
wherein the electronics tray is configured to rotate between an operational position where the portion is located above the leak container and a servicing position where the portion is not located above the leak container.

2. The system according to claim 1, wherein the electronics tray is configured to rotate around an axis proximate an end of the electronics tray.

3. The system according to claim 1, wherein the electronics tray is configured to rotate around an axis perpendicular to a direction of gravity.

4. The system according to claim 1, wherein the electronics tray is configured to rotate approximately 180 degrees between the operational position and the servicing position.

5. The system according to claim 1, wherein the system includes a damping mechanism configured to slow a rotational speed of the electronics tray as it rotates between the operational position and the servicing position.

6. The system according to claim 5, wherein the damping mechanism includes: a torsional speed limiter, a biasing member, a hydraulic damping mechanism, or a pneumatic damping mechanism.

7. The system according to claim 1, wherein the system includes a holding mechanism configured to hold the electronics tray in the servicing position.

8. The system according to claim 1, wherein the system is configured to be mounted to an electronics drawer.

9. The system according to claim 8, wherein the electronics tray is configured to rotate around an axis perpendicular to a moving axis of the electronics drawer.

10. The system according to claim 1, wherein the electronics tray is rotatably mounted to the leak container via one or more hinges.

11. The system according to claim 10, wherein the hinges are between the leak container and the electronics tray.

12. The system according to claim 1, wherein the electronics tray and the leak container are mounted to an intermediate structure that includes one or more hinges.

13. The system according to claim 1, wherein the system is configured such that, when the mounting board is attached to the electronics tray, the liquid coolant system is:
below the mounting board in the operational position; and
above the mounting board in the servicing position.

14. A server comprising:
a chassis;
an electronics drawer configured to extend and retract relative to the chassis;
a leak container disposed within or attached to the electronics drawer; and
an electronics tray disposed within or attached to the electronics drawer,
wherein the electronics tray includes a mounting board with a liquid coolant system attached thereto, and
wherein the electronics tray is configured to rotate relative to the leak container between:
an operational position where the liquid coolant system is above the leak container; and
a service position where the liquid coolant system is not above the leak container.

15. The server according to claim 14, wherein the electronics tray is configured to rotate around an axis perpendicular to a moving axis of the electronics drawer.

16. The server according to claim 14, wherein the electronics tray is configured to rotate approximately 180 degrees between the operational position and the servicing position.

17. The server according to claim 14, wherein the electronics tray is configured to, when the electronics drawer is extended, rotate away from the chassis between the operational position and the servicing position and toward the chassis between the servicing position and the operational position.

18. A method of servicing a mounting board within a server, the mounting board having a liquid coolant system attached thereto, the method comprising:
extending an electronics drawer of the server, the electronics drawer including a system with an electronics tray having the mounting board attached thereto; and
rotating the electronics tray relative to a leak container of the system from an operational position where the liquid coolant system is above the leak container to a servicing position where the liquid coolant system is not above the leak container.

19. The method according to claim 18, wherein rotating the electronics tray relative to the leak container is facilitated via one or more hinges between the electronics tray and the leak container.

20. The method according to claim 18, wherein the method includes, after servicing the mounting board:
rotating the electronics tray relative to the leak container from the servicing position to the operational position; and
retracting the electronics drawer.
